(19) United States
(12) Patent Application Publication
(10) Pub. No.: US 2003/0137820 A1
(43) Pub. Date: Jul. 24, 2003

(54) Heat sink securing means with back plate

(76) Inventors: Wen Chun Chen, Tu-Chen (TW); Hsiang-Ping Chen, Tu-Chen (TW); Hao-Yun Ma, Tu-Chen (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/266,738

(22) Filed: Oct. 7, 2002

(30) Foreign Application Priority Data
Jan. 18, 2002 (TW) 09/1200433

(51) Int. Cl. H05K 9/00

(52) U.S. Cl. 361/816

(57) ABSTRACT

Heat sink securing means is adapted to accommodate a heat sink, and has a circuit board (20) sandwiched therein. The securing means includes a retention module (10), a back plate (30), and a plurality of screws (40). The retention module defines a plurality of through holes (12) therein. The back plate defines a plurality of engaging holes (32) corresponding with the through holes of the retention module. The screws extend through the through holes of the retention module and the circuit board, with lower ends of the screws threadedly engaging in the engaging holes of the back plate. The retention module, circuit board and back plate are thereby firmly and securely combined together.

### BACKGROUND OF THE INVENTION

1. Field of the Invention

The present invention relates to means for securing a heat sink onto a heat-generating electronic device mounted on a circuit board, and particularly to securing means including a back plate which has a simple configuration.

2. Description of Prior Art

In a typical personal computer, a heat sink is attached to a central processing unit (CPU) mounted on a mother board, for dispersing heat generated from the CPU. The heat sink is often secured to the mother board by a retention module, with the heat sink being received in the retention module.

FIG. 4 shows conventional means for securing a heat sink on a CPU. A retention module 50 is attached to a mother board 60. To reinforce the mother board 60 and fasten the retention module 50 to the mother board 60, a back plate 70 is attached to an underside of the mother board 60. The retention module 50, the mother board 60 and the back plate 70 are combined together by four screws 80 engaging with four nuts 90 embedded in the back plate 70. It is troublesome to embed the nuts 90, and time-consuming to assemble all the components together.

Therefore, new securing means to overcome the above-mentioned problems is desired.

### SUMMARY OF THE INVENTION

Accordingly, an object of the present invention is to provide heat sink securing means having a simple configuration.

Another object of the present invention is to provide heat sink securing means which is quickly and conveniently assembled.

In order to achieve the objects set out above, heat sink securing means in accordance with the present invention is adapted to accommodate a heat sink. The securing means has a circuit board sandwiched therein. The securing means comprises a retention module, a back plate, and a plurality of screws. The retention module defines a plurality of through holes therein. The back plate defines a plurality of engaging holes corresponding with the through holes of the retention module. The screws extend through the through holes of the retention module and the circuit board, with lower ends of the screws threadedly engaging in the engaging holes of the back plate. The retention module, circuit board and back plate are thereby firmly and securely combined together.

Other objects, advantages and novel features of the present invention will be drawn from the following detailed description of preferred embodiments of the present invention with attached drawings, in which:

### BRIEF DESCRIPTION OF THE DRAWINGS

FIG. 1 is an exploded perspective view of heat sink securing means in accordance with a preferred embodiment of the present invention, together with an intermediate circuit board;

FIG. 2 is an assembled view of FIG. 1;

FIG. 3 is an exploded perspective view of heat sink securing means in accordance with an alternative embodiment of the present invention, together with an intermediate circuit board; and

FIG. 4 is an exploded perspective view of conventional heat sink securing means.

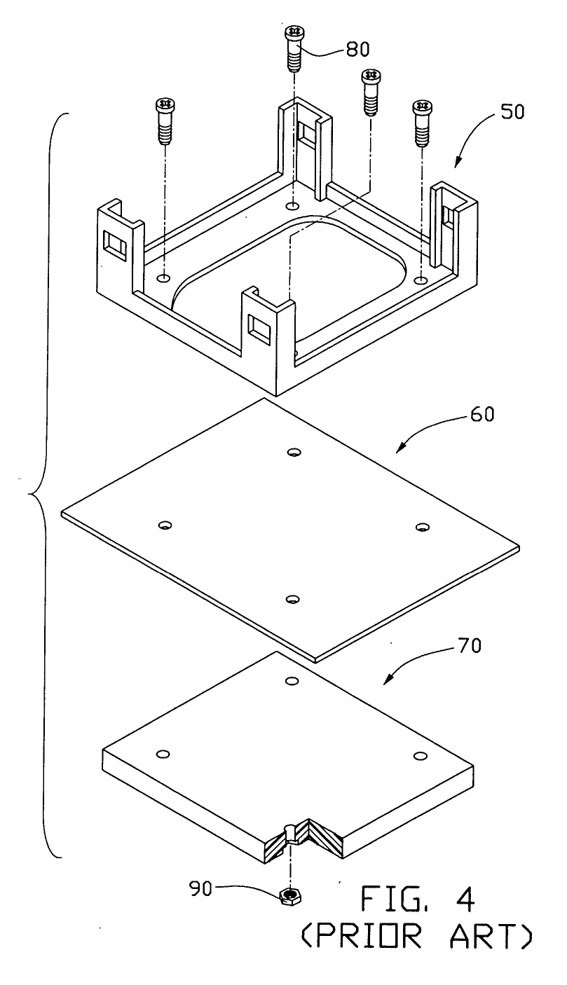

### DETAILED DESCRIPTION OF THE INVENTION

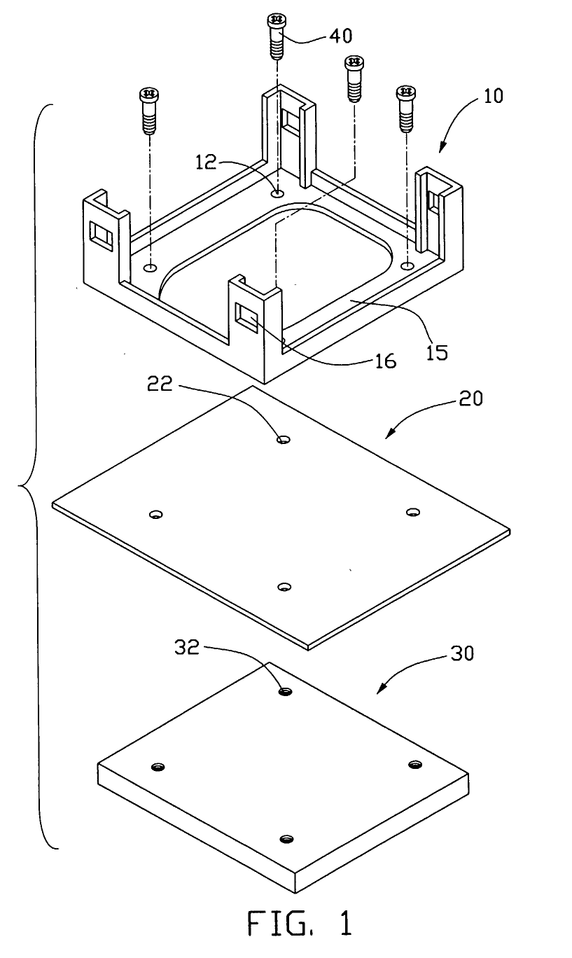

FIG. 1 is an exploded view of heat sink securing means in accordance with a preferred embodiment of the present invention. The securing means includes a heat sink retention module 10, a back plate 30, and four screws 40. A circuit board 20 is sandwiched between the retention module 10 and the back plate 30. Four through apertures 22 are defined in the circuit board 20.

The retention module 10 has a rectangular base 15, and four columns extending upwardly from four corners of the base 15 respectively. A locking slot 16 is defined in each column, for engagement with a heat sink (not shown) received in the retention module 10. A through hole 12 is defined in each corner of the base 15, corresponding to the through apertures 22 of the circuit board 20.

The back plate 30 is rectangular. Four threaded engaging holes 32 are defined in the back plate 30, corresponding with the through holes 12 of the retention module 10 and the through apertures 22 of the circuit board 20.

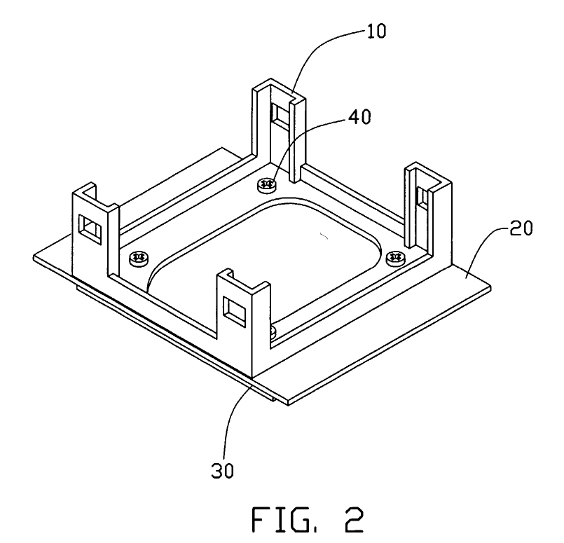

Also referring to FIG. 2, in assembly, the retention module 10, the circuit board 20 and the back plate 30 are placed together. The through holes 12, the through apertures 22 and the engaging holes 32 are aligned. The screws 40 are respectively extended through the through holes 12 and the through apertures 22, with lower ends of the screws 40 threadedly engaging in the corresponding engaging holes 32. The retention module 10, circuit board 20 and back plate 30 are thereby firmly and securely combined together.

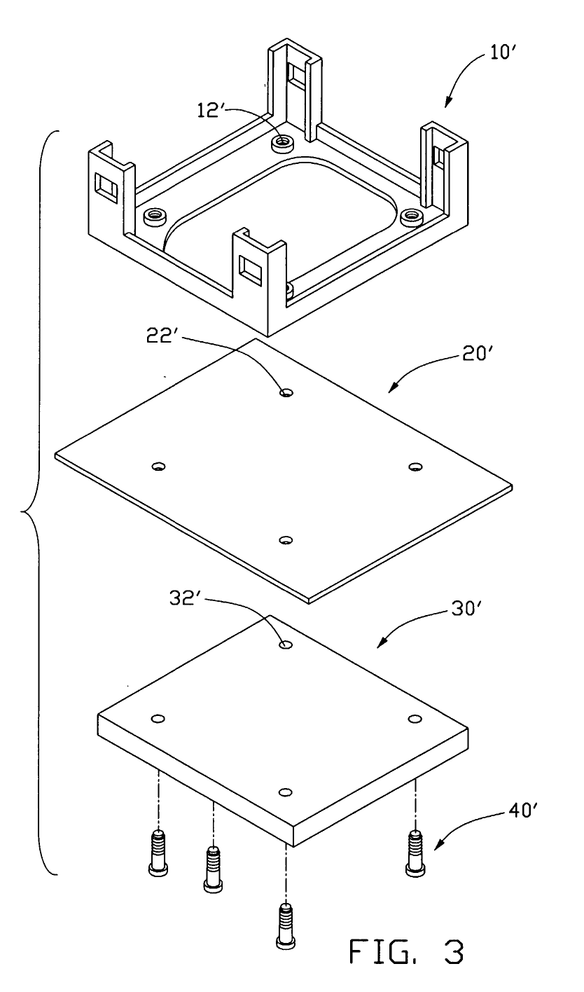

FIG. 3 shows heat sink securing means in accordance with an alternative embodiment of the present invention. The securing means includes a retention module 10′, a back plate 30′, and a plurality of screws 40′. A circuit board 20′ is sandwiched between the retention module 10′ and the back plate 30′. A threaded engaging hole 12′ is defined in each of four corners of a base of the retention module 10′. Four through holes 32′ are defined in the back plate 30′, corresponding to the engaging holes 12′. Four through apertures 22′ are defined in the circuit board 20′, corresponding to the through holes 32′ and the engaging holes 12′. In assembly, the retention module 10′, the circuit board 20′ and the back plate 30′ are placed together. The engaging holes 12′, the through apertures 22′ and the through holes 32′ are aligned. The screws 40′ are respectively extended upwardly from a bottom side of the back plate 40′ through the through holes 32′ and through apertures 22′, and threadedly engaged in the corresponding engaging holes 12′. The retention module 10′, circuit board 20′ and back plate 30′ are thereby firmly and securely combined together.

It is to be understood that the engaging holes 12′ may alternatively be through holes, and the screws 40′ may alternatively be self tapping screws. In assembly, the self tapping screws tap said through holes and engage therein.

It is to be further understood that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. Securing means adapted to accommodate a heat dispersing device and have
a circuit board sandwiched therein, the securing means comprising:
a retention module adapted for retaining the heat dispersing device, and having a plurality of holes defined therein;
a back plate defining a plurality of engaging holes corresponding with the holes of the retention module; and
a plurality of screws extending through the holes of the retention module and the circuit board, with lower ends of the screws threadedly engaging in the engaging holes of the back plate.

2. The securing means as described in claim 1, wherein the retention module has a base, and the holes are defined in the base.

3. The securing means as described in claim 1, wherein the retention module has a rectangular base, and four columns extend upwardly from four corners of the base.

4. The securing means as described in claim 1, wherein the back plate is rectangular.

5. The securing means as described in claim 1, wherein the engaging holes of the back plate are threaded holes.

6. The securing means as described in claim 1, wherein the screws are self tapping screws, and the screws tap the engaging holes of the back plate during assembly of the securing means.

7. Securing means adapted to accommodate a heat dispersing device and have a circuit board sandwiched therein, the securing means comprising:
a retention module adapted for retaining the heat dispersing device, and having a plurality of engaging holes defined therein;
a back plate defining a plurality of through holes corresponding with the engaging holes of the retention module; and
a plurality of screws extending through the through holes of the back plate and the circuit board, with upper ends of the screws threadedly engaging in the engaging holes of the retention module.

8. The securing means as described in claim 7, wherein the retention module has a base, and the engaging holes are defined in the base.

9. The securing means as described in claim 7, wherein the retention module has a rectangular base, and four columns extend upwardly from four corners of the base.

10. The securing means as described in claim 7, wherein the back plate is rectangular.

11. The securing means as described in claim 7, wherein the engaging holes of the retention module are threaded holes.

12. The securing means as described in claim 7, wherein the screws are self tapping screws, and the screws tap the engaging holes of the retention module during assembly of the securing means.

13. In combination,
a printed circuit board defining opposite first and second faces;
a retention module defining a base seated upon the first face of the printed circuit board and four bars extending around four corners of the base and away from said first face;
four first holes defined in the base adjacent to the corresponding bars, respectively;
a back plate abutting against the second face of the printed circuit board; four second holes defined in the back plate in vertical alignment with the corresponding first holes, respectively;
one of said first and second holes being threaded and the other being unthreaded; and
four screws each extending through the unthreaded one of said aligned first and second holes and threadedly terminated on the other; wherein
said each of said four screws has an enlarged head abuts against one of said base and said back plate, which said each of the screws extends through.
